(19) United States
(12) Patent Application Publication
(10) Pub. No.: US 2018/0046087 A1
(43) Pub. Date: Feb. 15, 2018

(54) NUMERICAL CALCULATION OF THE DIFFRACTION OF A STRUCTURE

(71) Applicants: Wolfgang IFF, Nurnberg (DE); Universite Jean Monnet Saint Etienne, Saint Etienne (FR); Centre National De la Recherche Scientifique, Paris (FR)

(72) Inventors: Wolfgang IFF, Nurnberg (DE); Alexandre TISHCHENKO, Lyon Cedex 08 (FR)

(73) Assignees: Universite Jean Monnet Saint Etienne, Saint Etienne (FR); Centre National De la Recherche Scientifique, Paris (FR)

(21) Appl. No.: 15/552,951

(22) PCT Filed: Feb. 22, 2016
(86) PCT No.: PCT/FR2016/050408

§ 371 Date: Aug. 23, 2017

(30) Foreign Application Priority Data
Feb. 24, 2015 (FR) 1551589

(51) Int. Cl. G03F 7/20; G06F 17/12

(52) U.S. Cl. CPC G03F 7/70158; G03F 7/705; G06F 17/12; G03F 7/70958

(57) ABSTRACT

The invention concerns a numerical calculation procedure of the diffraction of a structure (1) whose numerical model defines the dielectric permittivity at each point comprizing the steps of:
definition of a numerical modellization of the diffraction model of a structure including:
   the splitting of the numerical model of the dielectric permittivity into N numerical models of dielectric permittivity;
   the determination of the diffraction model of the said layers from the numerical model of this layer;
numerical calculation of the diffraction of the structure including:
   an initial iteration during which one performs:
      one wave propagation in the direction of layers 1 to N,
      and one wave propagation in the direction of the layers N to 1,
   ulterior iterations, each ulterior iteration of index k including:
      one wave propagation in the direction of layers 2 to N:
      one wave propagation in the direction of layers N−1 to 1.

The invention concerns the scattering/diffraction of an electromagnetic wave by complex material structures, in particular the modelling of scattering/diffraction properties and the numerical calculation of scattering/diffraction of heterogeneous structures of non-negligible thickness relative to the wavelength.

In a number of technical domains such as photolithography or diffractive optical elements it turns out to be essential to be able to accurately model and calculate the response of a component to an incident light beam. The modelling aims at calculating the diffraction of a structure characterized by the spatial distribution of the dielectric permittivity defined along different axes at each point of the structure.

The electromagnetic modelling of a structure is made in the present state of the art to allow either an approximate resolution procedure, or a statistical resolution procedure, or an exact resolution procedure.

The approximate resolution procedures permit to obtain a relatively fast diffraction calculation result. However, such procedures present an insufficient accuracy to obtain a satisfying calculation result.

The exact resolution procedures of the state of the art are very slow and require a very large numerical storage capacity which limits their application to optical elements of low complexity. The exact resolution procedures are therefore most often used only as spot checks of a modelling performed by an approximate resolution procedure.

Among the known exact resolution procedures of the state of the art, one can in particular mention the calculation procedure by means of the scattering matrices S. For this, the structure to be modelled is decomposed in a set of N contiguous layers and M diffraction orders. The scattering matrix Si of each layer of index i is calculated and permits to express the outgoing field amplitudes as a function of the amplitudes incident onto the two faces of this layer. One can thus note that an outgoing amplitude of a layer represents an incident amplitude of an adjacent layer.

$$( \begin{matrix}{f}_{i} \\ {b}_{i}\end{matrix} ) = {S}_{i} ( \begin{matrix}{f}_{i - 1} \\ {b}_{i + 1}\end{matrix} )$$

The S matrix of a component is formed by combining the set of the Si matrices of the different layers.

S=S₀∘S₁∘ . . . ∘S_{N-1}

The modelling then permits to determine the outgoing field amplitudes of the structure formed by the set of layers in function of the field amplitudes incident onto this structure:

$$( \begin{matrix}{f}_{N} \\ {b}_{0}\end{matrix} ) = S ( \begin{matrix}{f}_{0} \\ {b}_{N}\end{matrix} )$$

However, this Si matrix combination is not a simple product, but a complex calculation. The calculation time is proportional to M³ and in general linear in N.

A method alternative to the S matrix method is known from the original publication of Bremmer, and from the further development of Sluijter for the calculation of the transmission and the reflection of a system of superposed uniform layers by the a layer to layer calculation of the transmission and reflection of a plane wave from one side of the multilayer to the other followed by the same calculation in the opposite direction with the storage of the intermediate amplitudes, this back and forth calculation being repeated iteratively, and the results of the successive iterations being summed up until the sum converges. This method of back and forth propagation through the structure has been extended to diffractive structures composed of laterally microstructured layers, each step in a back and forth propagation calculating here the amplitude of the modes of each layer obtained by the method described in document D. M. Pai and K. A. Awada, “Analysis of dielectric gratings of arbitrary profiles and thicknesses”, J. Opt. Soc. Am. A 8, 755-762. The validity of this method was evaluated in the publication M. Nevière and F. Montiel, “Deep gratings: a combination of the differential theory and the multiple reflection series”, Opt. Commun. 108, 1-7 which concludes that this explicit summation of iterative results only converges for structures where the modulation of the refractive index, or of the interfaces, is weak and represents a perturbation of the basis structure.

Document EP2302360 describes a modelling procedure of the diffraction properties of periodic microscopic structures and a related procedure of diffraction calculation. The procedure expresses the problem in form of a volume integral of a vectorial field in replacement of the electric field. The vectorial field is obtained from the electric field by a change of basis so as to present a continuity at the material boundaries. Convolutions are made on the vectorial field by using convolution operators according to the finite Laurent series. One can thus carry out matrix products by means of fast Fourier transforms. A convolution and basis change operator is configured to transform the vectorial field to the desired electric field via a change of basis which is a function of the material properties and of the geometry of the periodic structure.

Document ‘New fast and memory-sparing method for rigorous electromagnetic analysis of 2D periodic dielectric structures’, by Shcherbakov and Tishchenko, published in the Journal of Quantitative Spectroscopy & Radiative Transfer, pages 158-171, describes another exact resolution procedure for the modelling of the electromagnetic properties of a structure. This procedure is in particular adapted to dielectric structures presenting a periodicity in a plane such as diffraction gratings.

The modelling procedure cuts the structure in different plane layers parallel to a XY plane in a Cartesian coordinate system XYZ. Each layer has a respective thickness along direction Z. A two-dimensional diffraction grating is modelled by a periodic variation of the dielectric permittivity of a layer along two different directions defined by the grating vectors in the XY plane.

The resolution procedure transforms the wave equation in form of an implicit integral equation. The resolution procedure then converts the wave equation in the reciprocal space along the axes X and Y. Because of the slicing of the structure in form of layers of same thicknesses, the integral formulation can be expressed in form of matrix equations corresponding to sums of harmonics and expressing the layer stack in form of sums. The normal and tangential electric field components are consequently separated. A block-Toeplitz matrix form can be established without necessitating matrix inversions. The resolution consists then in performing the inversion of a matrix which can be expressed as products of block-diagonal and block-Toeplitz matrices. The matrix inversion is in practice calculated by matrix multiplications by means of an iterative resolution method of linear equations of the GMRES type instead of a direct matrix inversion calculation. The block-Toeplitz form permits calculations by fast Fourier transforms with a calculation time substantially proportional to M, and a numerical memory resort also substantially proportional to M.

The calculation time obtained with this resolution procedure is proportional to N for simple structures of small thickness. However, the calculation time and the memory usage increase rapidly with the layer thicknesses of the structure to be modelled. A large number of iterations is then necessary to obtain a convergence of the iterative method which translates in a noticeable increase of the calculation time and of the needed numerical memory. Besides, the resolution method turns out to be ill-suited for structures comprizing very different layer structure heterogeneities, which questions some hypotheses of the resolution method. Further, the calculation remains demanding in the amount of numerical memory used since the resolution data of the whole structure must be stored during the whole calculation. This amount of needed calculation memory limits strongly the thickness of the structures that can be modelled.

Document U.S. Pat. No. 6,898,537 describes a numerical calculation procedure of the diffraction of a structure. A numerical model of the structure defines the dielectric permittivity at each of its points. The procedure defines a numerical modelling of a diffraction model of the structure including a split of the model in a number N of numerical models of superposed plane layers. The procedure determines the diffraction model of each layer from the numerical model of dielectric permittivity of this layer. The procedure describes the numerical calculation of the diffraction of the structure based on the propagation of a wave through the layers in a given direction.

The document published by David Windt entitled << IMD-Software for modeling the optical properties of multilayer films” in Computers in Physics., volume 12, No 4, Jan. 1, 1998, page 360, describes a numerical calculation procedure of the optical characteristics of a multilayer structure whose numerical model defines the dielectric permittivity at each point.

Document EP1804126 describes a numerical calculation procedure for the diffraction of a structure whose numerical model defines the dielectric permittivity at each point. This procedure comprizes the definition of a numerical modelling of a diffraction model of the structure. This definition of the numerical modelling comprizes the split of the dielectric permittivity numerical model of the structure in a number N of dielectric permittivity numerical models of superposed plane layers.

The invention aims at solving one or a number of these drawbacks. The invention relates to a numerical calculation procedure for the diffraction of a structure of which a numerical model defines the dielectric permittivity at each point as defined in the claims.

Other characteristics and advantages of the invention shall appear clearly in the following description for non-limiting indicative purpose with reference to the annexed drawings in which:

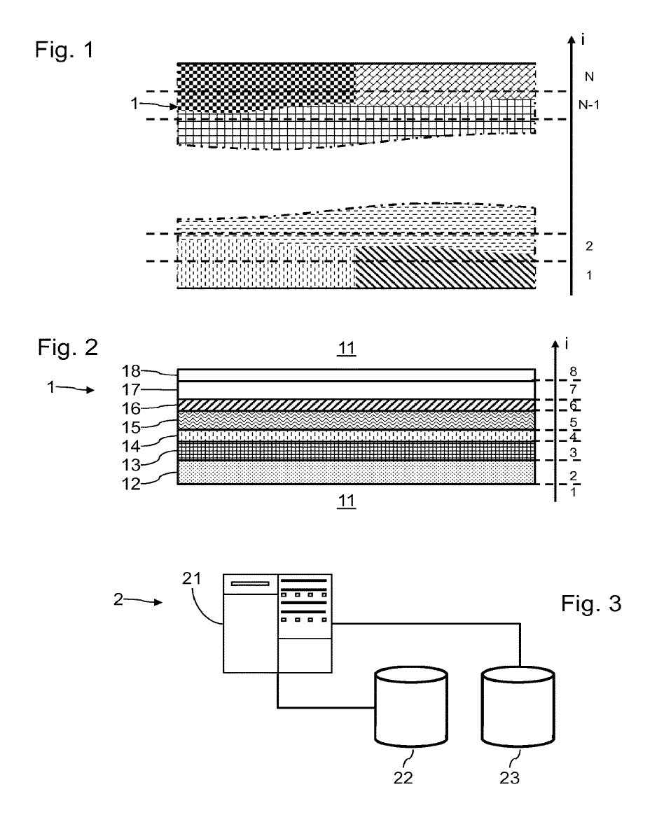

FIG. 1 is the cross-sectional view of an example of structure to be modelled split in different layers

FIG. 2 is a schematic cross-sectional view of an example of simplified structure to be modelled of the OLED type split in different layers

FIG. 3 represents schematically a system configured for modelling and numerically calculating the diffraction of a structure

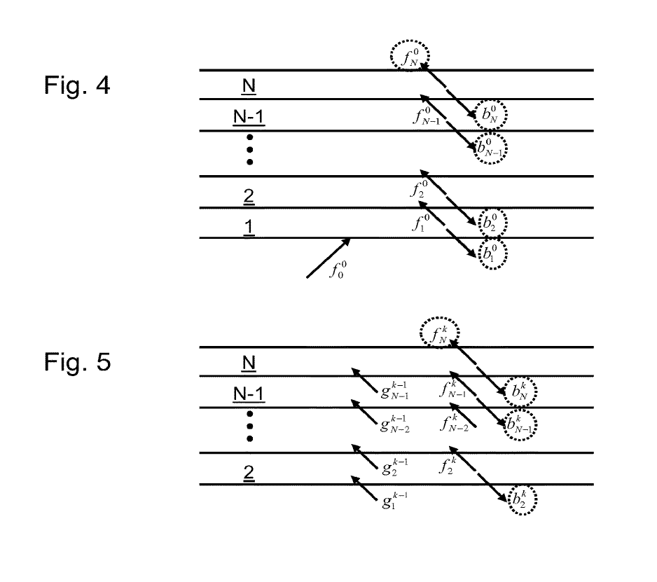

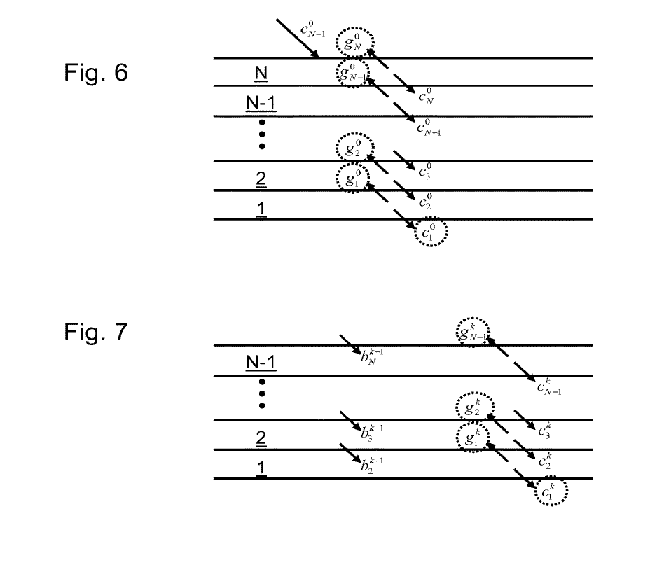

FIG. 4 and FIG. 6 represent schematically different parameters calculated during a first phase of a calculation procedure

FIG. 5 and FIG. 7 represent schematically different parameters calculated during a later phase of the calculation procedure

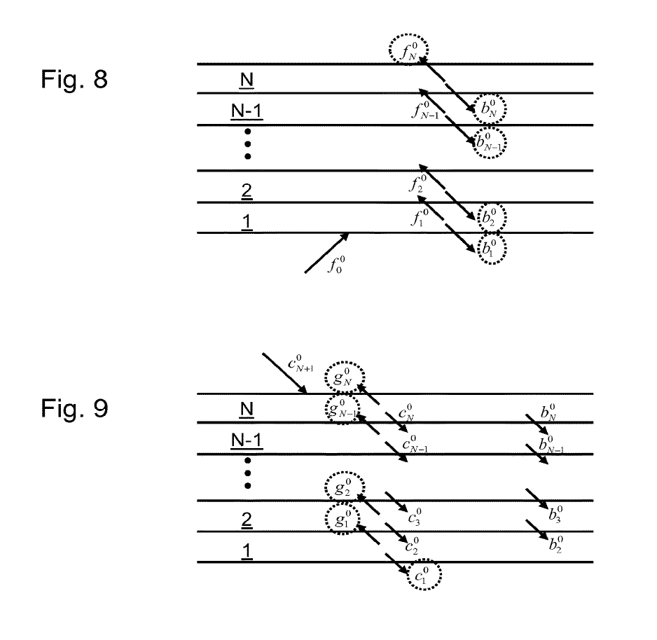

FIG. 8 and FIG. 9 represent schematically different parameters calculated during a first iteration of a calculation procedure according to another variant

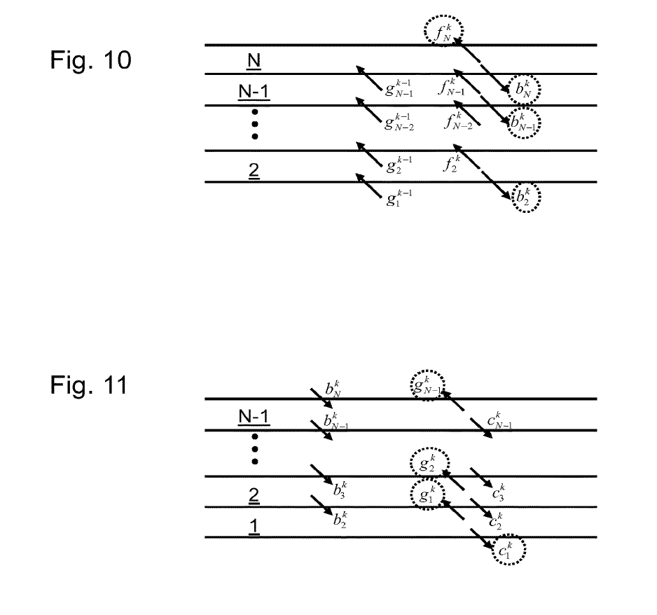

FIG. 10 and FIG. 11 represent schematically different parameters calculated during later iterations of a calculation procedure according to this another variant

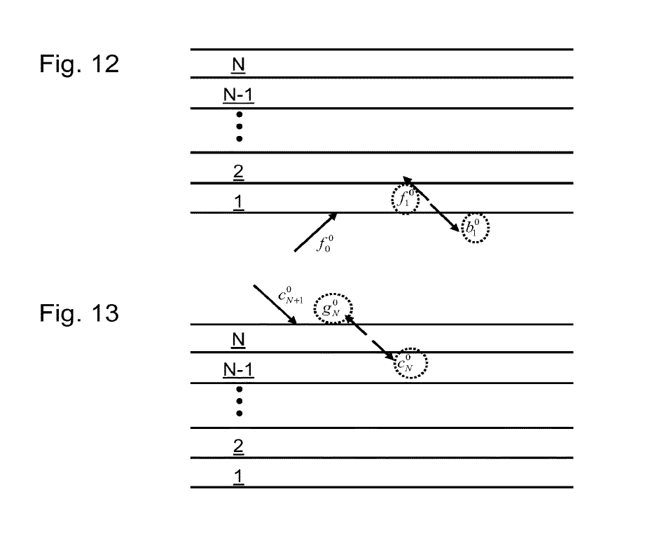

FIG. 12 and FIG. 13 represent schematically different parameters calculated during a first iteration of a calculation procedure according to yet another variant

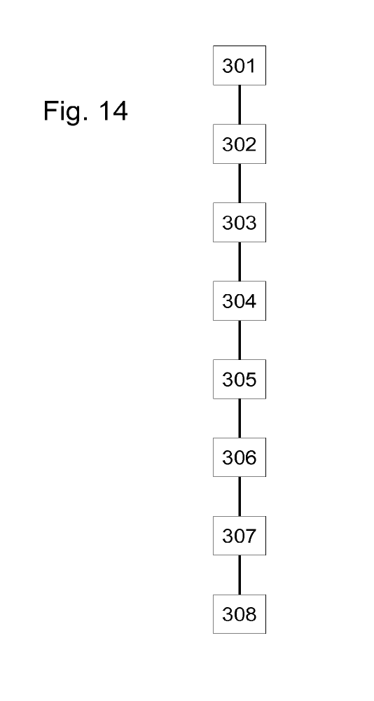

FIG. 14 illustrates a flowchart of an example of numerical calculation procedure of the diffraction of a structure

FIG. 1 is a cross-sectional view of an example of structure 1 to be modelled. Structure 1 presents here a parallelepiped structure with an upper and a lower plane face whereon electromagnetic waves can be incident. Structure 1 comprizes here different zones, for instance realized in different materials presenting distinct dielectric permittivity distributions.

A numerical model of the dielectric permittivity of structure 1 at each point (for a given resolution of the numerical model) is known. The dielectric permittivity of structure 1 is thus determined at each of its points, or determinable by a law (of distribution for instance) at each of its points.

A first aspect of the invention aims at defining a numerical model of the diffraction of structure 1 for the application of incident electromagnetic waves onto the upper and/or the bottom face. The invention particularly aims at defining such numerical model to permit a diffraction calculation whose amount of numerical memory used is proportional to the number M of considered diffraction orders.

The invention can be implemented by a system of numerical treatment 2 illustrated in FIG. 3. Such numerical treatment system 2 can for instance include a calculation device 21 (for instance a server having an adequate system of exploitation and calculation application), a storage device 22 for the dielectric permittivity numerical model, and a storage device 23 for the calculation results. Storage device 23 can for instance store numerical diffraction models (detailed hereafter) of different layers of structure 1, or the numerical diffraction model of the whole structure 1.

An example of numerical modelling procedure according to the first aspect of the invention can be the following. The dielectric permittivity numerical model of structure 1 is first split into a number N of dielectric permittivity numerical models. Each of these dielectric permittivity numerical models corresponds to a respective plane layer of structure 1, the different layers being superposed along a direction perpendicular to the upper and bottom faces of structure 1. Each layer is identified by its index i, index i increasing between the bottom face and the upper face of structure 1 with values comprized between 1 and N as illustrated in FIG. 1.

For sake of simplification, the different layers have here the same thickness. The invention could however also be applied to a split of structure 1 into layers of different thicknesses. For instance, FIG. 2 is a cross-sectional view of another example of structure 1 to be modelled. FIG. 2 corresponds to a simplified scheme of the OLED type. The different layers of the numerical model are here chosen according to the functions of the different layers of structure 1, these different layers presenting typically different thicknesses. The numerical models of the different layers will thus include for instance a numerical model of an air layer 11, a numerical model of a glass layer 12, a numerical model of a scattering layer 13, a numerical model of a transparent electrode 14, a numerical model of a polymer layer 15, a numerical model of an emitting layer 16, a numerical model of a polymer layer 17, and a numerical model of a metallic electrode 18.

The number N of layers is chosen so that each layer is sufficiently thin so that a diffraction model for each layer could be determined from its dielectric permittivity numerical model and that the diffraction model of each layer could be calculated with a numerical memory occupation lower or equal to K*M. Advantageously, this number N of layers is chosen so that each layer is sufficiently thin for a diffraction model of each layer to be calculated within a time shorter or equal to K*M*log(M). K is a factor independent of M, typically a constant.

The determination of the diffraction model of each layer can for instance be implemented by the procedure named GSM (Generalized Source Method) hereafter, and described in document ‘New fast and memory-sparing method for rigorous electromagnetic analysis of 2D periodic dielectric structures’, Shcherbakov and Tishchenko, published in the Journal of Quantitative spectroscopy & Radiative Transfer, pages 158-171.

The diffraction model of each layer i can for instance be noted as a linear operator Lᵢ such as:

$$( \begin{matrix}{f}_{i} \\ {b}_{i}\end{matrix} ) = {L}_{i} ( \begin{matrix}{f}_{i - 1} \\ {b}_{i + 1}\end{matrix} )$$

where fᵢ₋₁ and bᵢ₊₁ are the amplitudes of the M diffraction orders of the waves incident onto the faces of layer i, and fᵢ, and bᵢ are the amplitudes of the M orders diffracted by layer i. The operator Lᵢ can be obtained by the Generalized Source Method (GSM) described in A. A. Shcherbakov, A. V. Tishchenko, “New fast and memory-sparing method for rigorous electromagnetic analysis of 2D periodic dielectric structures”, J. Quant. Spectrosc. Rad. Transfer 113, 158-171 (2012), or by an analytic formulation for layers that are very thin relative to the wavelength as described in A. V. Tishchenko, “Analytical solutions of 2D grating diffraction: GSM versus Rayleigh hypothesis,” Proc. SPIE 5249 p. 683-694 (2004), or can even be the S matrix in the case of simple layers where S is of the Toeplitz or block-diagonal type.

According to a second aspect of the invention, one realizes a diffraction calculation of at least one incident wave from the diffraction models of the N layers. In so doing, after the determination of the diffraction models of the N layers, diffraction calculations can be carried out for different incident waves from these diffraction models.

According to a first variant of diffraction calculation, one performs in parallel a propagation calculation with application of an incident wave onto layer 1 and a propagation calculation by the application of an incident wave onto layer N. If the usage of the numerical memory can be better optimized than with this first variant (here a memory occupancy proportional to 2M*(N+1)), the latter turns out to be particularly appropriate to be implemented by parallel calculation means, for instance systems with multiple processors or graphic cards.

For the propagation calculation based on the application of an incident wave incident onto layer 1, an initial iteration (iteration of order 0) of the procedure is illustrated with reference to FIG. 4.

M incident diffraction orders whose amplitudes are contained in vector f₀⁰ are applied to the diffraction model of layer 1 onto its external face. The M transmitted diffraction orders whose amplitudes are contained in vector f₁⁰ are calculated by means of this diffraction model, and the M reflected orders b₁⁰ are calculated and stored.

Then, for each layer of index i comprized between 2 and N, one applies the M calculated transmitted orders fᵢ₋₁⁰ into the diffraction model of the layer of index i. One Calculates the M transmitted orders fᵢ⁰, and one calculates and stores the M reflected orders bᵢ⁰. For the layer of index N one stores additionally the M transmitted orders f_{N}⁰. The stored elements are illustrated inside the dotted circles in FIG. 4.

During this initial iteration one applies the operator Lᵢ as follows in the absence of the incidence b_{N+1}⁰:

$$( \begin{matrix}{f}_{i}^{0} \\ {b}_{i}^{0}\end{matrix} ) = {L}_{i} ( \begin{matrix}{f}_{i - 1}^{0} \\ 0\end{matrix} )$$

For the propagation calculation based on the application of the M orders incident onto layer N, an initial iteration of the procedure is illustrated with reference to FIG. 6.

The incident orders c_{N+1}⁰ are applied to the diffraction model of layer N onto its external face. The transmitted orders c_{N}⁰ are calculated with this diffraction model and the reflected orders g_{N}⁰ are calculated and stored.

Then, for each layer of index i comprized between N−1 et 1, one applies the calculated transmitted order cᵢ₊₁⁰ in the diffraction model of the layer of index i. One calculates the transmitted orders cᵢ⁰, and one calculates and stores the reflected orders gᵢ⁰. For the layer of index 1 one stores additionally the transmitted orders c₁⁰. The stored elements are illustrated inside the dotted circles in FIG. 6.

During this initial iteration one applies in practice the Lᵢ operator as follows in the absence of incidence gᵢ₋₁⁰:

$$( \begin{matrix}{g}_{i}^{0} \\ {c}_{i}^{0}\end{matrix} ) = {L}_{i} ( \begin{matrix}0 \\ {c}_{i + 1}^{0}\end{matrix} )$$

One calculates the outgoing amplitudes of the initial iteration by adding the amplitudes of the orders incident onto an external face and the amplitudes of the orders reflected by this same face:

f⁰=f_{N}⁰+g_{N}⁰

b⁰=b₁⁰+c₁⁰

One notes v⁰ a basis amplitude vector forming a basis solution containing the amplitudes inside the structure:

$${v}^{0} = \{ \begin{matrix}{g}_{i}^{0} \\ {b}_{i + 1}^{0}\end{matrix} \}$$

with all i corn prized between 1 and N−1.

This initial iteration necessitates a calculation time proportional to the number N of layers and a memory occupancy proportional to 2M*(N+1).

This basis solution v⁰ does not correspond to the solution retained later. The retained solution is determined after supplementary iterations of the diffraction calculation as detailed hereafter.

The vector v of the amplitudes of the final solution containing the amplitudes of all diffraction orders of all layers is determined from the basis solution v⁰ by successive iterations. Each iteration is followed by a convergence test to determine whether the solution vector of the iteration is a final solution.

Each iteration can be expressed by means of an operator P in the form v^{k}=P·v^{k-1} with k the iteration index. In principle the desired solution adds up the set of iteration vectors. The desired vectorial solution v is the solution of the implicit equation v=v⁰+P·v

This implicit equation is true for every linear electromagnetic system and results from the application of the d'Ewald-Oseen theorem described in document Max Born, Emil Wolf, (1999), Principles of Optics (7th ed.), Cambridge University Press, §2.4.

At each iteration of index k>0, one proceeds to an upgoing propagation between layers 2 and N of each vector gᵢ₋₁^{k-1} added to each vector fᵢ₋₁^{k}, and a downgoing propagation of each vector bᵢ₊₁^{k-1} added to each vector cᵢ₊₁^{k}, between layers N−1 and 1.

For the upgoing propagation one applies in practice the Lᵢ operator as follows as illustrated in FIG. 5:

$$( \begin{matrix}{f}_{i}^{k} \\ {b}_{i}^{k}\end{matrix} ) = {L}_{i} ( \begin{matrix}{g}_{i - 1}^{k - 1} + {f}_{i - 1}^{k} \\ 0\end{matrix} )$$

with f₁^{k}=0.

Then one stores bᵢ^{k} and f_{N}^{k}.

For the downgoing propagation one applies the Lᵢ operator as follows as illustrated in FIG. 7:

$$( \begin{matrix}{g}_{i}^{k} \\ {c}_{i}^{k}\end{matrix} ) = {L}_{i} ( \begin{matrix}0 \\ {g}_{i + 1}^{k - 1} + {c}_{i + 1}^{k}\end{matrix} )$$

with c_{N}^{k}=0.

Then one stores gᵢ^{k} et c₁^{k}.

Each iteration necessitates a calculation time proportional to the number N of layers and a memory occupancy proportional to 2M*(N+1).

The final vectorial solution v is the solution of the implicit equation v=v⁰+P·v. One makes a convergence test after each iteration. The convergence test is part of a resolution method of a system of linear equations defined by the implicit equation above.

The resolution of the implicit equation is for instance based on the GMRES method which is usually used to obtain iteratively the numerical solution of a system of linear equations without matrix inversion. The GMRES solution is in particular described in document ‘Iterative Methods for Sparse Linear Systems’ of Saad, second edition of ‘Society for Industrial and Applied Mathematics’, published in 2003 (ISBN 978-0-89871-534-7).

The GMRES solution usually aims at solving the system of linear equations of the type:

A·x=b

Matrix A is supposed invertible and of size (m×m). Furthermore one supposes that b is normalized, i.e., ∥b∥=1, ∥·∥ representing here the Euclidian norm.

The n^{th} Krylov space for this problem is defined as:

Kₙ={Vect}{b,A·b,A²·b, . . . ,A^{{n-1}}·b}

where Vect corresponds to the generated vectorial subspace.

The GMRES method gives an approximation of the exact solution of A·x=b by the vector xₙ ∈ Kₙ which minimizes the norm of the residue: ∥A·xₙ−b∥.

To ensure the linearly independent character of vecteurs b, A·b, . . . , Aⁿ⁻¹·b, one uses the Arnoldi method to find the orthonormal vectors q₁, q₂, . . . , qₙ which constitute a basis of Kₙ. So, the vector xₙ ∈ Kₙ can be written xₙ=Qₙyₙ with yₙ ∈ Rₙ, and Qₙ a matrix of size (m×n) formed of the q₁, q₂, . . . , qₙ.

The Arnoldi method also produces an upper Hessenberg matrix \tilde{H}ₙ of size (n+1)·xₙ with

A·Qₙ=Qₙ₊₁·\tilde{H}ₙ

As Qₙ is orthogonal, one has

∥A·xₙ−b∥=∥\tilde{H}ₙ·yₙ−β·e₁∥

where e₁=(1, 0, 0, . . . , 0) is the first vector of the canonical basis of Rₙ₊₁ and β=∥b−A·x₀∥, with x₀ an initialization vector (for instance null). So, xₙ can be found by minimizing the norm of the residue rₙ=\tilde{H}ₙ·yₙ−β·e₁

Each iteration of the GMRES method algorithm usually includes:
Carrying out one step of the Arnoldi algorithm;
Finding out yₙ which minimizes ∥rₙ∥;
Calculating xₙ=Qₙ·yₙ;
Resuming the calculations as long as the residue is larger than a quantity (said tolerance) chosen arbitrarily at the beginning of the algorithm.

For applying the GMRES method to the convergence test of the invention one substitutes the operation (x−P·x) to the multiplication operation A·x mentioned above.

The vectorial space Wₖ=(v₀ v₁ . . . vₖ), ∥V∥=1 of Krylov is formed by using

$${v}_{0} = \frac{{v}_{0}}{‖ {v}_{0} ‖} , {v}_{0}^{*} {v}_{0} = 1$$

The * after a vector defines its transpose and conjugate.

The application of an iterative step vₖ−P·vₖ permits to create a new vector vₖ₊₁ and to enlarge the Krylov space up to Wₖ₊₁.

The normalization operation of vectors vₖ defines the Hessenberg matrix H_{i,k}:

$${H}_{i , k} = \{ \begin{matrix}{v}_{i}^{*} ( {v}_{k} - P \cdot {v}_{k} ) , & i \leq k \\ ‖ {v}_{k} - P \cdot {v}_{k} - {\sum }_{j = 0}^{k} {v}_{j}^{*} \cdot {H}_{jk} ‖ , & i = k + 1\end{matrix}$$

so that vₖ−P·vₖ=vₖ₊₁*·Hₖ

[symbol]

ₖ−PV=Vₖ₊₁*Hₖ

The Hessenberg matrix Hₖ is represented in the form Hₖ=Qₖ₊₁·Rₖ

where Rₖ is an upper right matrix, i.e., a matrix in which the extra-diagonal elements under the diagonal are zero and where Qₖ₊₁ is a rotation/reflection matrix with ∥Qₖ₊₁∥=1

The solution xₖ is searched for in the Wₖ space as a linear superposition of vectors vₖ taken with the coefficients yₖ:

$${x}_{k} = {\sum }_{j = 0}^{k - 1} {y}_{j} \cdot {v}_{j}$$

One shows that the best choice of y for the solution xₖ is:

y=∥v₀∥(Rₖ)⁻¹Qₖ₊₁*e₀

In this case the error norm is minimum:

min∥rₖ∥=∥v₀∥Q_{0,k+1}*

The error norm is calculated at each step of the GMRES method iterative algorithm. One compares the error norm to a pre-defined threshold. If the calculated error norm is larger than the threshold, a new propagation iteration is calculated. If the error norm is smaller than the threshold, one concludes that the calculated solution is sufficiently close to the final solution to stop the propagation iterations.

Due to the criterion for the choice of the number N of layers (determined so that a diffraction model of each layer could be calculated from its dielectric permittivity numerical model with a numerical memory occupancy smaller or equal to K*M), the GMRES method is applicable even with calculation means having limited memory resorts, and the maximum thickness of a structure that can be modelled is strongly increased.

At a last step, after the convergence criterion has been satisfied with the iteration index k:
One finds the vectorial solution between the layers to calculate the fields within the layers

$$\{ \begin{matrix}{g}_{i} \\ {b}_{i + 1}\end{matrix} \} = {\sum }_{j = 0}^{k - 1} {y}_{j} \cdot {v}_{j}$$

for every i comprized between 1 and N−1.
One thus finds the vectorial solution at the exit of the structure

$$\{ \begin{matrix}f \\ b\end{matrix} \} = \{ \begin{matrix}{f}_{N}^{0} + {g}_{N}^{0} \\ {b}_{1}^{0} + {c}_{1}^{0}\end{matrix} \} + {\sum }_{j = 1}^{k} {y}_{j - 1} \cdot \{ \begin{matrix}{g}_{N}^{j} \\ {c}_{1}^{j}\end{matrix} \}$$

One has detailed here a convergence test based on a GMRES method; however, other resolution methods for linear equation systems can be used for a convergence test applied to an implicit equation as the biconjugate gradient stabilized method (BCGS).

At the final iteration one performs an upgoing propagation between layers 2 and N of each vector gᵢ₋₁ added to each vector fᵢ₋₁, and one performs a downgoing propagation of each vector bᵢ₊₁ added to each vector cᵢ₊₁ between layers N−1 et 1. The advantage is to permit to find the vectorial solution between the layers.

So, for the upgoing propagation one applies the operator Lᵢ as illustrated in FIG. 5:

$$( \begin{matrix}{f}_{i} \\ {b}_{i}\end{matrix} ) = {L}_{i} ( \begin{matrix}{g}_{i - 1} + {f}_{i - 1} \\ 0\end{matrix} )$$

with f₁=0 and with i comprized between 2 and N.

One then stores b₁ and f_{N}.

For the downgoing propagation one applies the Lᵢ operator as illustrated in FIG. 7:

$$( \begin{matrix}{g}_{i} \\ {c}_{i}\end{matrix} ) = {L}_{i} ( \begin{matrix}0 \\ {b}_{i + 1} + {c}_{i + 1}\end{matrix} )$$

with c_{N}=0 and for every i comprized between N−1 and 1.

One then stores g_{N} and c₁.

This final iteration necessitates a calculation time proportional to the number N of layers and a memory occupancy proportional to 4M. One then finds the vectorial solution at the exit of the structure

$$\{ \begin{matrix}f \\ b\end{matrix} \} = \{ \begin{matrix}{f}_{N}^{0} + {g}_{N}^{0} \\ {b}_{1}^{0} + {c}_{1}^{0}\end{matrix} \} + \{ \begin{matrix}{f}_{N} + {g}_{N} \\ {b}_{1} + {c}_{1}\end{matrix} \}$$

According to a modification of the algorithm one calculates the reflected amplitudes of the initial iteration on the external faces:

f⁰=g_{N}⁰

b⁰=b₁⁰

The basis vector v⁰ is enlarged as it also comprizes the amplitudes f_{N}⁰ and c₁⁰. At each iteration of index k>0, one adds the amplitudes f_{N}^{k}, and c₁^{k} with the v^{k} vector to find an enlarged vector. The final solution found by such iterative method comprizes the amplitudes f_{N} and c₁. The amplitudes f et b at the exit of the structure are found by addition with the reflected amplitudes of the initial iteration:

$$\{ \begin{matrix}f \\ b\end{matrix} \} = \{ \begin{matrix}{g}_{N}^{0} \\ {b}_{1}^{0}\end{matrix} \} + \{ \begin{matrix}{f}_{N} \\ {c}_{1}\end{matrix} \}$$

This modification results in a larger memory occupancy proportional to (N+1) for each iteration. As from there one does not need the final iteration, the total number of iterations is thus decreased.

According to a second variant one performs sequentially the application of a propagation in one direction, then one applies the reflected orders in the opposite direction. This second variant permits to optimize the use of the numerical memory with an occupancy proportional to a M*(N+1).

At an initial iteration (or iteration of index 0) of the procedure illustrated in reference with FIG. 8 one realizes as an example a propagation of the diffraction orders incident onto layer 1.

The vector of the incident orders f₀⁰ is applied to the diffraction model of layer 1 on its external face. The transmitted orders f₁⁰ are calculated with this diffraction model and the reflected orders b₁⁰ are calculated and stored.

Then, for each layer of index i comprized between 2 and N one applies the calculated transmitted orders fᵢ₋₁⁰ in the diffraction model of the layer of index i. One calculates the transmitted orders fᵢ⁰, and one calculates and stores the amplitudes of the reflected orders bᵢ⁰. For the layer of index N one stores in addition the amplitudes of the transmitted orders f_{N}⁰. The stored elements are illustrated inside the dotted circles of FIG. 8.

During this initial iteration one applies the Lᵢ operator as follows in the absence of incidence bᵢ₊₁⁰:

$$( \begin{matrix}{f}_{i}^{0} \\ {b}_{i}^{0}\end{matrix} ) = {L}_{i} ( \begin{matrix}{f}_{i - 1}^{0} \\ 0\end{matrix} )$$

The initial iteration continues with the application of the incident orders c_{N+1}⁰ to the diffraction model of layer N on its external face. The transmitted orders c_{N}⁰ are calculated with this diffraction model and the reflected orders g_{N}⁰ are calculated and stored.

Then, for each layer of index i comprized between N−1 et 1, one adds the calculated transmitted orders cᵢ₊₁⁰ and the reflected orders calculated previously bᵢ₊₁⁰ in the diffraction model of the layer of index i.

One calculates the amplitudes of the transmitted orders cᵢ⁰, and one calculates and stores the amplitudes of the reflected orders gᵢ⁰. For the layer of index 1 one stores additionally the amplitudes of the transmitted orders c₁⁰. The stored elements are illustrated inside the dotted circles of FIG. 9. In order to optimize the amount of numerical memory used after the calculation of the transmitted orders cᵢ⁰ and of the vector gᵢ⁰, one can free the numerical memory occupied by the amplitudes of the orders bᵢ₊₁⁰ calculated previously.

During this initial iteration one applies the Lᵢ operator as follows in the absence of incidence gᵢ₋₁⁰:

$$( \begin{matrix}{g}_{i}^{0} \\ {c}_{i}^{0}\end{matrix} ) = {L}_{i} ( \begin{matrix}0 \\ {c}_{i + 1}^{0} + {b}_{i + 1}^{0}\end{matrix} )$$

One calculates the outgoing amplitudes of the initial iteration by adding the amplitudes of the orders incident onto an external face and the amplitudes of the orders reflected by this face:

f⁰=f_{N}⁰+g_{N}⁰

b⁰=b₁⁰+c₁⁰

One notes v₀⁰ a basis vector forming a basis solution with the amplitudes inside the structure:

v⁰={gᵢ⁰}

with all i comprized between 1 and N−1.

This initial iteration necessitates a calculation time proportional to the number N of layers. Because of the deallocation of the numerical memory occupied by the calculated orders bᵢ₊₁⁰, this initial iteration requires a memory occupancy proportional to a M*(N+1).

This basis solution v⁰ does not correspond to the solution retained later. The retained solution is determined after supplementary iterations as detailed hereafter.

As for the first variant, vector v of the final solution is determined from the basis solution v⁰ by successive iterations. Each iteration is followed by a convergence test as detailed previously to determine whether the solution vector is a final solution.

Each iteration can be expressed by means of an operator P in the form v^{k}=P·v^{k-1} with k the iteration index. The vectorial solution v is the solution of the implicit equation v=v⁰+P·v

At each iteration of index k>0 one performs an upgoing propagation between layers 2 and N of each vector fᵢ₋₁^{k}, considering f₁^{k}=0, added to each vector gᵢ₋₁^{k-1}, and one stores each resulting vector bᵢ^{k}. One then performs a downgoing propagation of each vector cᵢ₊₁^{k} added to each vector bᵢ₊₁^{k} between layers N−1 and 1, considering c_{N}^{k}=0, and one stores each resulting vector gᵢ^{k}.

So, for the upgoing propagation one applies the Lᵢ operator as follows as illustrated in FIG. 10:

$$( \begin{matrix}{f}_{i}^{k} \\ {b}_{i}^{k}\end{matrix} ) = {L}_{i} ( \begin{matrix}{g}_{i - 1}^{k - 1} + {f}_{i - 1}^{k} \\ 0\end{matrix} )$$

with f₁^{k}=0.

One then stores bᵢ^{k}.

After each calculation of bᵢ^{k}, one deallocates the numerical memory occupied by gᵢ₋₁^{k-1}.

For the downgoing propagation one applies the Lᵢ operator as follows as illustrated in FIG. 11:

$$( \begin{matrix}{g}_{i}^{k} \\ {c}_{i}^{k}\end{matrix} ) = {L}_{i} ( \begin{matrix}0 \\ {b}_{i + 1}^{k} + {c}_{i + 1}^{k}\end{matrix} )$$

with cₙ^{k}=0.

One then stores gᵢ^{k}.

After each calculation of gᵢ^{k} one deallocates the numerical memory occupied by bᵢ₊₁^{k}.

Each iteration requires a calculation time proportional to the number N of layers and a numerical memory occupancy proportional to M*(N+1).

As for the first variant one performs a convergence test at the end of each iteration to solve the implicit equation v=v⁰+P·v. The convergence test also uses a resolution method of a system of linear equations to search for the solution of this implicit equation without matrix inversion.

At the final iteration one performs an upgoing propagation between layers 2 and N of each vector gᵢ₋₁ added to each vector fᵢ₋₁, and one performs a downgoing propagation of each vector cᵢ₊₁, between layers N−1 and 1. For the upgoing propagation one applies the Lᵢ operator as follows as illustrated in FIG. 10:

$$( \begin{matrix}{f}_{i} \\ {b}_{i}\end{matrix} ) = {L}_{i} ( \begin{matrix}{g}_{i - 1} + {f}_{i - 1} \\ 0\end{matrix} )$$

with f₁=0.

One then stores bᵢ.

After each calculation of bᵢ one deallocates the numerical memory occupied by gᵢ₋₁.

For the downgoing propagation one applies the Lᵢ operator as follows as illustrated in FIG. 11:

$$( \begin{matrix}{g}_{i} \\ {c}_{i}\end{matrix} ) = {L}_{i} ( \begin{matrix}0 \\ {b}_{i + 1} + {c}_{i + 1}\end{matrix} )$$

with c_{N}=0.

One then stores gᵢ.

After each calculation of gᵢ, one deallocates the numerical memory occupied by bᵢ₊₁.

This final iteration requires a calculation time proportional to the number N of layers and a memory occupancy proportional to M*(N+1). One then finds the vectorial solution at the exit of the structure

$$\{ \begin{matrix}f \\ b\end{matrix} \} = \{ \begin{matrix}{f}_{N}^{0} + {g}_{N}^{0} \\ {b}_{1}^{0} + {c}_{1}^{0}\end{matrix} \} + \{ \begin{matrix}{f}_{N} \\ {c}_{1}\end{matrix} \}$$

According to a modification of the algorithm, the basis vector v⁰ is enlarged by comprizing the amplitudes f⁰ and c⁰. At each iteration of index k>0 one adds the amplitudes f_{N}^{k} and c₁^{k} with the vector v^{k} to find an enlarged vector. The amplitudes f and b at the exit of the structure are found by addition with the reflected amplitudes of the initial iteration:

$$\{ \begin{matrix}f \\ b\end{matrix} \} = \{ \begin{matrix}{g}_{N}^{0} \\ {b}_{1}^{0}\end{matrix} \} + \{ \begin{matrix}{f}_{N} \\ {c}_{1}\end{matrix} \}$$

This modification results in a larger memory occupancy proportional to (N+1) for each iteration; as from here one does not need the final iteration, the total number of iterations is thus decreased.

According to a third variant, one performs in parallel a propagation calculation by the application of an incident wave on layer 1 and a propagation calculation by the application of an incident wave on layer N. The usage of the numerical memory is the same as in the first variant (a memory occupation proportional to 2M*(N+1)); the propagation calculation is more parallelizable, which turns out to be particularly appropriate to be implemented by means of a large number of parallel calculation means (for instance at least 4, or with a number of parallel calculation means at least equal to one quarter of the number N of layers), for instance systems of multiple processors or graphic cards. For sake of simplification one will now consider a specific example in which one performs a number of calculations in parallel equal to the number N of layers.

For the propagation calculation based on the application of a wave incident onto layer 1, an initial iteration (or iteration of index 0) of the procedure is illustrated with reference to FIG. 12.

M incident diffraction orders whose amplitudes are contained in vector f₀⁰ are applied to the diffraction model of layer 1 on its external face. The M transmitted diffraction orders whose amplitudes are contained in vector f₁⁰ are calculated with this diffraction model and stored, and the M reflected orders b₁⁰ are calculated and stored:

$$( \begin{matrix}{f}_{1}^{0} \\ {b}_{1}^{0}\end{matrix} ) = {L}_{i} ( \begin{matrix}{f}_{0}^{0} \\ 0\end{matrix} )$$

For this initial iteration one only calculates the transmitted orders b₁⁰ and the reflected orders g_{N}⁰. One supposes for all other amplitudes of the transmitted orders:

bᵢ⁰=0

for every i comprized between 2 and N.

Fort the propagation calculation based on the application of the M incident orders on layer N an initial operation of the procedure is illustrated with reference to FIG. 13.

The incident orders c_{N+1}⁰ are applied to the diffraction model of layer N on its external face. The transmitted orders c_{N}⁰ are calculated with this diffraction model and stored and the reflected orders g_{N}⁰ are calculated and stored.

$$( \begin{matrix}{g}_{N}^{0} \\ {c}_{N}^{0}\end{matrix} ) = {L}_{i} ( \begin{matrix}0 \\ {c}_{N + 1}^{0}\end{matrix} )$$

One supposes for all other amplitudes of the reflected orders:

gᵢ⁰=0

for every i comprized between 1 and N−1

One notes v⁰ a basis vector forming a basis solution with the amplitudes f⁰ and b⁰

$${v}^{0} = \{ \begin{matrix}{g}_{i}^{0} \\ {b}_{i + 1}^{0}\end{matrix} \}$$

for every i comprized between 1 and N−1.

This initial iteration requires the calculation time of one layer since the calculation is parallelized, and a memory occupancy proportional to 4M. To find out the exact solution of the diffraction problem, iterations are needed and are described hereafter.

As for the first and second variants, the vector v of the amplitudes of the final solution is determined from the basis solution v⁰ by the successive iterations. Each iteration is followed by a convergence test as detailed previously to determine whether the solution vector of the iteration can be considered as a final solution.

Each iteration can be expressed by means of an operator P in the form v^{k}=P·v^{k-1} with k the iteration index. The vectorial solution v is the solution of the implicit equation v=v⁰+P·v

At each iteration of index k>0 one performs a propagation of each vector gᵢ₋₁^{k-1} added to each vector bᵢ₊₁^{k}, of layer i. Such calculation is performed in parallel for each layer of index i between 1 and N:

$$( \begin{matrix}{g}_{i}^{k} \\ {b}_{i}^{k}\end{matrix} ) = {L}_{i} ( \begin{matrix}{g}_{i - 1}^{k - 1} \\ {b}_{i + 1}^{k - 1}\end{matrix} )$$

with g₀^{k-1}=0 and b_{N+1}^{k-1}=0.

Each iteration requires a calculation time of one layer and a memory occupancy proportional to 2M*(N−1).

As for the two first variants one performs a convergence test at the end of each iteration for solving the implicit equation v=v⁰+P·v. The convergence test also uses a resolution method of a system of linear equations to find the solution of this implicit equation without matrix inversion.

At the final iteration one performs a propagation of vector gₙ₋₁ towards layer N:

$$( \begin{matrix}{f}_{N} \\ *\end{matrix} ) = {L}_{N} ( \begin{matrix}{g}_{N - 1} \\ 0\end{matrix} )$$

and a propagation of vector c₁ towards layer 1:

$$( \begin{matrix}* \\ {b}_{1}\end{matrix} ) = {L}_{N} ( \begin{matrix}0 \\ {c}_{1}\end{matrix} )$$

Such calculation is performed in parallel for the two layers 1 and N with g₀^{k-1}=0 and b_{N+1}^{k-1}=0.

This iteration requires the calculation time for one layer and a memory occupancy proportional to 2M.

The vectorial solution at the exit of the structure is found as the sum

$$\{ \begin{matrix}f \\ b\end{matrix} \} = \{ \begin{matrix}{f}_{N}^{0} + {f}_{N} \\ {b}_{1}^{0} + {b}_{1}\end{matrix} \}$$

According to a modification of the algorithm, the basis vector v⁰ is enlarged as it also comprizes the amplitudes f⁰ and c⁰. At each iteration of index k>0 one adds the amplitudes f_{N}^{k} and c₁^{k} with the vector v^{k} to find an enlarged vector. The amplitudes f and b at the exit of the structure are found by addition with the reflected amplitudes of the initial iteration:

$$\{ \begin{matrix}f \\ b\end{matrix} \} = \{ \begin{matrix}{g}_{N}^{0} \\ {b}_{1}^{0}\end{matrix} \} + \{ \begin{matrix}{f}_{N} \\ {c}_{1}\end{matrix} \}$$

This modification results in a larger memory occupancy proportional to (N+1) for each iteration, and as from here one does not need the final iteration, thus the total number of iterations is decreased.

FIG. 14 represents schematically an example of a series of steps for the implementation of a numerical calculation procedure of a diffractive structure.

At step 301, one defines a numerical model of the dielectric permittivity of a structure at each of its points.

At step 302, the dielectric permittivity numerical model of the structure is split into N dielectric permittivity numerical models, each numerical model corresponding to a plane layer of the structure, these plane layers being superposed along a direction perpendicular to the upper and bottom faces of the structure. The layers corresponding to the splitting of the dielectric permittivity numerical model of the structure are determine so that the diffraction model of each layer can be calculated from ist dielectric permittivity numerical model with a calculation time shorter or equal to K*M*log(M).

At step 303, one determines a diffraction model for each of the N layers from its dielectric permittivity numerical model. The diffraction model of each layer i can for instance be noted as an operator Lᵢ such that:

$$( \begin{matrix}{f}_{i} \\ {b}_{i}\end{matrix} ) = {L}_{i} ( \begin{matrix}{f}_{i - 1} \\ {b}_{i + 1}\end{matrix} )$$

with fᵢ₋₁ and bᵢ₊₁ the incident amplitudes on the faces of layer i and fᵢ and bᵢ the amplitudes diffracted by layer i.

At step 304, one performs an initial propagation iteration of the incident orders through the diffraction models of the structure layers

At step 305, one performs a propagation iteration of the orders diffracted and calculated at the previous iteration through the diffraction models of the structure layers.

At step 306, one performs a convergence test of the last propagation iteration of diffracted orders by using a resolution method of a system of linear equation without matrix inversion, and by applying it to the desired resolution of the implicit equation for the convergence of the iterations. If the convergence test condition is not satisfied, one resumes step 305 for a new propagation iteration of the diffracted orders.

At step 307, one performs an ultimate propagation iteration of the orders diffracted and calculated at the previous iterations through the diffraction models of the structure layers.

The numerical calculation procedure of the diffraction of a structure described in the above examples can be applied to different technical domains of which a non-exhaustive list is presented hereafter by way of example.

In diffractive optics, for the design of structures comprizing micro- and nano-structures (micro- and nano-structures whose characteristic dimension is smaller than 3 to 5 times the wavelength), the diffraction properties depend on the polarization, and the usual scalar methods model them erroneously. The calculation procedures of the invention permit to simulate large sections of such periodic or non-periodic structures, or even a complete structure. Such calculation procedure can for instance be applied to a refractive-diffractive lens of minimum weight and dimension used in an ultra-fast optical read and write system.

A calculation procedure of the invention can also be applied to scattering optics. Such calculation procedure can in particular be applied for optimizing the desired distribution of mono- or poly-chromatic light by a scattering layer. Such scattering layer comprizes typically a host medium containing microspheres or micro-polyhedrons of refractive index different from that of the host medium. The scattering layer illuminates uniformly a screen, shedding light in a desired fashion in a volume from a localized light source or a luminous wall. While permitting to rigorously model large sections of such scattering layers, the described calculation procedure accounts for the effects of multiple scattering in a layer and coherence effects.

Such calculation procedure can also be used in scattering optics for the optimization of a scattering layer aimed at the efficient extraction of the light generated for instance by a light source of the LED (Light Emitting Diode) type or by an organic electroluminescent diode (OLED).

A calculation procedure according to the invention can also be applied in microelectronics for the optimization of the different processes in photolithography, in particular when the characteristic dimensions of the features at the level of the reticle and/or at the level of the silicon wafer is of the order or smaller than the projection wavelength. This is particularly the case for the technological nodes of 45, 30 nm, and below at the wavelengths of KrF (248 nm) and ArF (193 nm) excimer lasers. One of the processes to be carried out at the reticle level is the OPC Optical Proximity Correction. Such correction implies the exact calculation of the reticle transmission under variable incidence conditions, the reticle including features of different depth in materials like SiO₂, chromium, MoSiO, TaO.

The usual transmission calculation methods for such structures are scalar methods with euristic correctives inspired from local exact calculations. The usage of these correctives permits to preserve the calculation speed of scalar methods but their validity is limited. A calculation procedure according to the invention permits to notably extend the boundary between the domain of the structures modelisable exactly into that of the structures calculable approximately.

Another process in microelectronic photolithography is that of the modelling of the latent image in a photoresist layer spread on a substrate. The topography and the surface composition result from a number of previous process steps which notably affects the incident light power distribution by diffraction in reflection. The scalar methods of the state of the art are confronted with big difficulties as the structure below the photoresist layer where the latent image is projected can be very complex and thick. The calculation procedure of the invention permits to account for the real structure.

1. Procedure of numerical calculation of the diffraction of a structure whose numerical model defines the dielectric permittivity at each point comprizing the steps of:
definition of a numerical modelling of a diffraction model of a structure including:
the splitting of the numerical model of dielectric permittivity of the structure in a number N of dielectric permittivity numerical models of respective plane layers superposed along a direction and ordered according to an index i comprized between 1 and N along said direction;
determination of the diffraction model of each said layer from the dielectric permittivity numerical model of this layer, the number N of layers being determined so as the numerical memory occupancy for the diffraction calculation by the diffraction model of each layer is smaller than K*M with M the number of diffraction orders of this layer and K a factor independent of M;
numerical calculation of the diffraction of the structure including:
an initial iteration during which one performs:
one wave propagation in the direction of layers 1 to N including:
the calculation of a reflected wave and of a transmitted wave by application of an incident wave to the diffraction model of the layer of index 1;
for a layer of index i comprized between 2 and N, calculation of a reflected wave and of a transmitted wave by application of an incident wave to the diffraction model of layer i, this incident wave being the transmitted wave calculated for the layer of index i−1;
storage of the reflected waves calculated for each of the layers of index i, and of the transmitted wave calculated for the layer of index N;
and one wave propagation in the direction of layers N to 1 including:
a reflected wave and a transmitted wave are calculated by application of an incident wave to the diffraction model of the layer of index N;
for a layer of index i comprized between N−1 and 1, a reflected wave and a transmitted wave are calculated by application of an incident wave to the diffraction model of the layer of index i, this incident wave including the transmitted wave calculated for the layer of index i+1;
storage of the reflected waves calculated for each of the layers of index i, and of the transmitted wave calculated for the layer of index N;
ulterior iterations, each ulterior iteration of index k including:
one wave propagation in the direction of layers 2 to N including:
for a layer of index i comprized between 2 and N, calculation of a reflected wave and of a transmitted wave by application of an incident wave to the diffraction model of the layer of index i, this incident wave including the transmitted wave calculated for the layer of index i−1 during this iteration and including the reflected wave calculated for the layer of index i−1 during the last propagation in the opposite direction;
storage of the reflected waves calculated for each of the layers of index i, and of the transmitted wave calculated for the layer of index N;
one wave propagation in the direction of the layers N−1 to 1 including:
for a layer of index i comprized between N−1 and 1, calculation of a reflected wave and of a transmitted wave by application of an incident wave to the diffraction model of the layer of index i, this incident wave including the transmitted wave calculated for the layer of index i+1 during this iteration and including the reflected wave calculated for the layer of index i+1 during the last propagation in the opposite direction;
storage of the reflected waves calculated for each of the layers of index i, and of the transmitted wave calculated for the layer of index 1,
a convergence test of the solution Vₖ formed of the reflected and transmitted waves calculated in the iteration of index k by application of an iterative resolution method of linear equation systems to the resolution of the implicit equation of convergence Vₖ=P·Vₖ with P an operator corresponding to the transformation of the solution of every solution Vₖ₋₁ into a solution Vₖ at the iteration k.

2. Numerical calculation procedure according to claim 1 wherein said iterative resolution method of linear equation systems is a method of the GMRES type.

3. Numerical calculation procedure according to claim 1 wherein said iterative resolution method of linear equation systems is a biconjugate gradient stabilized method.

4. Numerical calculation procedure according to claim 1 wherein said determination of the diffraction model of each of said layers is implemented by a GSM procedure.

5. Numerical calculation procedure according to claim 1 wherein N is at least equal to 5.

6. Numerical calculation procedure according to claim 1 wherein the propagation calculation in the direction of layers 2 to N and the propagation calculation in the direction of layers N−1 to 1 are performed in parallel.

7. Numerical calculation procedure according to claim 1 wherein the propagation calculation in the direction of layers 2 to N and the propagation calculation in the direction of layers N−1 to 1 are performed sequentially.

8. Numerical calculation procedure according to claim 1 wherein the propagation calculation comprizes calculations in parallel for different layers.
